(19) United States
(12) Patent Application Publication
(10) Pub. No.: US 2024/0274488 A1
(43) Pub. Date: Aug. 15, 2024

(54) THERMAL CONDUCTIVE MEMBER FOR A HEAT SINK

(71) Applicant: The ESAB Group Inc., North Bethesda, MD (US)

(72) Inventor: Secundino Miguel Baldonado, West Lebanon, NH (US)

(21) Appl. No.: 18/108,330

(22) Filed: Feb. 10, 2023

(51) Int. Cl. H01L 23/367; F28F 3/02; H01L 23/373

(52) U.S. Cl. CPC H01L 23/3672; F28F 3/02; H01L 23/3736

(57) ABSTRACT

A cooling system is used to cool one or more electrical devices. An additional component is incorporated into a heat sink block to improve the ability of the heat sink to cool a heat-generating electrical device. One or more thermally conductive members are incorporated into heat sink fins to improve cooling an electrical device that is in thermal contact with the conductive members. Alternatively, one or more thermally conductive members are placed proximate to and in contact with heat sink fins to improve the cooling of an electrical device. The thermally conductive member is made of a material having a higher thermal conductivity than the material of the heat sink block.

### FIELD OF THE INVENTION

The present invention relates to the field of cooling heat-producing devices and, in particular, to a heat sink that can be used to cool a heat-producing device.

### BACKGROUND OF THE INVENTION

Typically, electrical devices generate heat during operation. Often, electrical devices in a power supply system are cooled using a traditional heat sink, which is usually made of a single metal material that is integrally formed into a block having multiple fins extending therefrom. One problem is that several electrical devices in the same power supply are attached to the same heat sink, and as a result, one or more of the electrical devices are insufficiently cooled by the heat sink they share. Collectively, all of the electronic devices coupled to a common heat sink must be cooled based on the hottest or most overheating electrical devices. In particular, the temperature of each electrical device must remain below its maximum-permitted temperature, which may be specified by a company manufacturing the electrical device.

A more specific problem with conventional cooling systems is that, in some instances, the temperature of the electrical devices must be reduced below the maximum-permitted temperature of the devices (1) without using a fan, which would require additional power; (2) without increasing the size of the heat sink, e.g., by increasing the mass of the heat sink; and (3) without changing the material of the entire heat sink, which could lead to a significantly more expensive heat sink. Accordingly, existing cooling mechanisms have proved insufficient to cool certain electrical devices that have a propensity to overheat in power supply systems.

### SUMMARY

The present application relates to a cooling system that is used to cool one or more electrical devices. According to the invention, an additional component is incorporated into a heat sink block to improve the ability of the heat sink to cool a heat-generating electrical device. In one embodiment, one or more thermally conductive members are incorporated into heat sink fins to improve cooling an electrical device that is in thermal contact with the conductive members. In another embodiment, one or more thermally conductive members are placed proximate to and in contact with heat sink fins to improve the cooling of an electrical device. The thermally conductive member is made of a material having a higher thermal conductivity than the material of the heat sink block.

In one embodiment, the invention relates to a heat sink for use with a heat-producing device. The heat sink includes a body having a fin extending therefrom, the body being formed of a first material, the body being coupleable to the heat-producing device so that the body is in direct contact with the heat-producing device, and a solid cooling component coupled to the body, the solid cooling component being formed of a second material, the second material being different from the first material, the second material having a higher thermal conductivity than the first material.

In one embodiment, the solid cooling component may be rod-shaped. In other embodiments, the solid cooling component may have any cross-sectional shape. In one embodiment, the heat-producing device includes a die, and the solid cooling component is placed in contact with a surface of the heat-producing device directly over the location of the die for maximum heat transfer. In another embodiment, the solid cooling component has an outer surface that includes threads formed thereon. In yet another embodiment, the solid cooling component has an outer surface that is uneven, the uneven outer surface increasing the cooling ability of the solid cooling component.

Also, the body includes an opening formed therein, and the opening receives the solid cooling component when the solid cooling component is coupled to the body. In addition, the opening extends through the body, and when inserted into the opening, the solid cooling component extends through the body and is positioned to directly contact the heat-producing device. Alternatively, the solid cooling component has a first end, and the opening receives the first end of the solid cooling component. In addition, an end surface of the first end directly contacts a particular location on the heat-producing device when the body is placed into engagement with the heat-producing device.

In one embodiment, the solid cooling component contacts the fin. In another embodiment, the solid cooling component is substantially in line with the fin. Also, the first material is aluminum and the second material is copper. Alternatively, the first material has a thermal conductivity of less than 240 W/m*K and the second material has a thermal conductivity greater than or equal to 400 W/m*K.

In an alternative embodiment, the invention relates to a heat sink for use with a heat-producing device, with the heat sink including a body having a plurality of fins extending therefrom, the body being formed of a first material, the body being placeable in direct contact with a surface of a heat-producing device, and a first solid cooling component coupled to the body proximate to a first fin of the plurality of fins, the first solid cooling component being formed of a second material different from the first material, and the second material having a higher thermal conductivity than the first material.

In one embodiment, the body includes a first opening formed therein and extending through the body, and the first solid cooling component is inserted into the first opening of the body and placeable in direct contact with the surface of the heat-producing device. In another embodiment, the first solid cooling component is an elongate member. In addition, the first solid cooling component is substantially in line with the first fin. In one embodiment, the body includes a second opening formed therein, and the heat sink further includes a second solid cooling component coupled to the body, wherein the second solid cooling component is formed of the second material, and the second solid component is inserted into the second opening in the body. In addition, the second solid cooling component either contacts a second fin of the plurality of fins or is located substantially in line with the second fin.

In another embodiment, the invention relates to a heat sink including a block formed of a first material, the block having a plurality of fins extending therefrom, the block being placeable into engagement with a heat-producing device, and a cooling component coupled to the block, the cooling component being solid and formed of a second material, the second material being different from the first material, the second material having a higher thermal conductivity than the first material.

In one embodiment, the block includes an opening, the cooling component is insertable into the opening, and the opening and the cooling component are in contact with one of the plurality of fins. In another embodiment, the block includes an opening, the cooling component is insertable into the opening, and the opening and the cooling component are in line with one of the plurality of fins.

### BRIEF DESCRIPTION OF THE DRAWINGS

The various apparatuses, systems, devices, and/or components presented herein may be better understood with reference to the following drawings and description. It should be understood that some elements in the figures may not necessarily be to scale and that emphasis has been placed upon illustrating the principles disclosed herein. In the figures, like-referenced numerals designate corresponding parts throughout the different views.

FIG. 1 is a block diagram of an embodiment of a heat sink according to the present invention.

FIG. 2 is a side view of another embodiment of a heat sink according to the present invention.

FIG. 3 illustrates a perspective view of the heat sink illustrated in FIG. 2.

FIG. 4 illustrates a side view of an embodiment of a cooling component according to the present invention.

FIG. 5 illustrates a perspective view of an embodiment a heat sink according to the present invention.

FIG. 6 illustrates an end view of the heat sink illustrated in FIG. 5.

FIG. 7 illustrates a bottom view of the heat sink illustrated in FIG. 5.

FIG. 8 illustrates a perspective view of another embodiment of a heat sink according to the present invention.

FIG. 9 illustrates a side perspective view of a prior art power source for a cutting system, with an external cover of the power source removed.

### DETAILED DESCRIPTION

In the following detailed description, reference is made to the accompanying figures which form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the description herein. Alternate embodiments of the present disclosure and their equivalents may be devised without parting from the spirit or scope of the present disclosure. It should be noted that any discussion herein regarding “one embodiment”, “an embodiment”, “an exemplary embodiment”, and the like indicate that the embodiment described may include a particular feature, structure, or characteristic, and that such particular feature, structure, or characteristic may not necessarily be included in every embodiment. In addition, references to the foregoing do not necessarily comprise a reference to the same embodiment. Finally, irrespective of whether it is explicitly described, one of ordinary skill in the art would readily appreciate that each of the particular features, structures, or characteristics of the given embodiments may be utilized in connection or combination with those of any other embodiment discussed herein.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). Also, the terms “comprising,” “including,” “having,” and the like, as used with respect to embodiments of the present disclosure, are synonymous.

The present invention relates to cooling systems for use with electrical devices. In particular, the invention relates to cooling systems for use with electrical devices that generate heat during operation and need to be cooled so that the electrical device does not exceed a maximum desired temperature. An exemplary electrical device or heat-generating device is a power supply of a cutting or welding system.

According to the invention, an additional cooling component is incorporated into a heat sink block to improve the ability of the heat sink to cool a heat-generating electrical device. In one implementation, one or more thermally conductive members or plugs are incorporated into heat sink fins to improve the cooling of an electrical device that is in thermal contact with the conductive members. In another implementation, one or more thermally conductive members or plugs are placed proximate to heat sink fins. The thermally conductive members or plugs are preferably made of a material having a higher thermal conductivity than the material of the heat sink block to which the thermally conductive members are coupled. The higher thermal conductivity of the members results in an improvement in the cooling properties of the heat sink when one or more thermally conductive members are coupled to the heat sink block.

In one example embodiment, the heat sink block is made of aluminum, which has a thermal conductivity of less than 240 Watts per meter-kelvin (“W/(m*K)”) (approximately 237 W/(m*K)), and the conductive member is made of pure copper, which has a thermal conductivity of approximately 400 W/(m*K). In other embodiments of the invention, other conductive materials could be used for the conductive member disclosed herein, provided that the other conductive materials have a higher thermal conductivity than the heat sink block. For example, the heat sink block can have a thermal conductivity of less than 240 W/m*K and the conductive member can have a thermal conductivity greater than or equal to 400 W/m*K.

In one embodiment of the invention, the conductive member is rod-shaped. In another embodiment, the conductive member is inserted into a hole or opening or bore in the heat sink block. In yet another embodiment, the conductive member directly contacts the heat-producing electrical device. In an alternative embodiment, the conductive member contacts a fin of the heat sink. In yet another alternative embodiment, the conductive member is substantially in line with a heat sink fin such that the conductive member does not substantially interfere with the airflow across the heat sink fins and between the heat sink fins.

In another embodiment, the conductive member includes exterior threads on an outer peripheral surface of the conductive member such that the conductive member can be screwed into the heat sink body and fins. In this embodiment, the threads of the conductive member may increase the conductive heat transfer of the conductive rod. In other embodiments, the conductive member is positioned adjacent to one of the fins, or alternatively, the conductive member is not necessarily required to contact a fin at all. While one conductive member is discussed for some embodiments of the invention, any number of conductive members could be added to a heat sink block, and these conductive members may be in thermal contact with one or more of heat-producing electrical devices.

One of the advantages of using a higher thermal conductivity member or component, such as copper, in a heat sink is so that certain areas can be targeted to accomplish higher cooling results. The targeting of certain areas allows for control of the range of heat transfer from the electrical device to the heat sink. In one exemplary application, it is desired to reduce a large temperature difference between a PCB die and the surface temperature of a heat sink in contact with the electrical device. In another exemplary application in which multiple devices are coupled to a large heat sink, there may be only one device that is exceeding a desired maximum temperature. Using one or conductive members can solve this problem by specifically locating the conductive members either directly in contact with or proximate to that particular device.

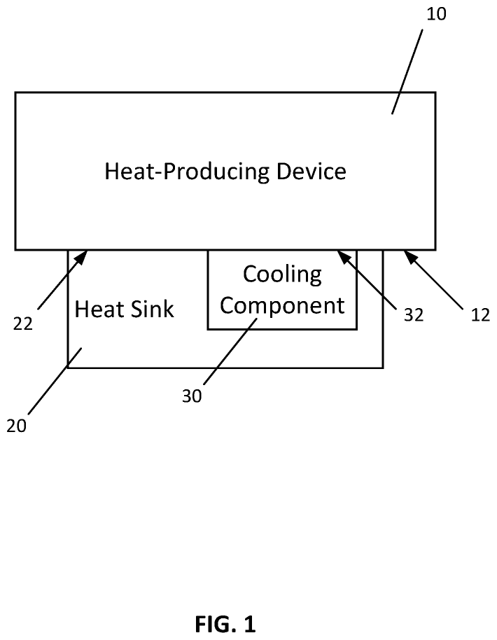

Referring to FIG. 1, a block diagram illustrating an embodiment of a heat sink according to the present invention is shown. Several components are illustrated in FIG. 1, and it is to be appreciated that the relative sizes of the components are illustrative only and can vary in different embodiments of the invention. A heat-producing device 10, alternatively referred to herein as an electrical device, is shown with a surface 12. A heat sink 20 with a surface 22 is placed into contact with surface 12 of the heat-producing device 10.

The heat sink 20 includes a cooling component 30 coupled thereto. According to the present invention, the cooling component 30 is a solid material that has a higher thermal conductivity than the material of the rest of the heat sink 20, which may include a block with several fins or blades extending therefrom. As a result, when one or more cooling components 30 are coupled to the heat sink 20, the overall cooling effectiveness and properties of the heat sink 20 are improved. In other words, the combination of one or more cooling components 30 with the heat sink 20 can cool the heat-producing device 10 better than the heat sink 20 alone. This is due to the higher thermal conductivity of the cooling component and its ability to absorb more heat from the electrical device. In one embodiment, as shown in FIG. 1, the cooling component 30 has a surface 32 that is placed into contact with the surface 12 of the heat-producing device 10. The contact between surfaces 12 and 32 increases the exchange of heat and thermal energy therebetween.

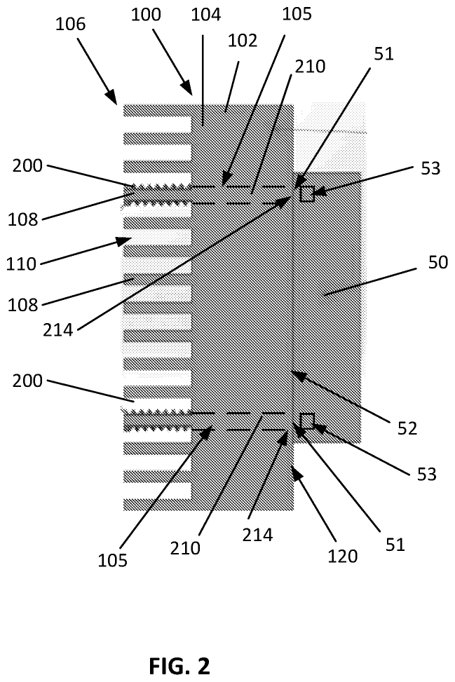

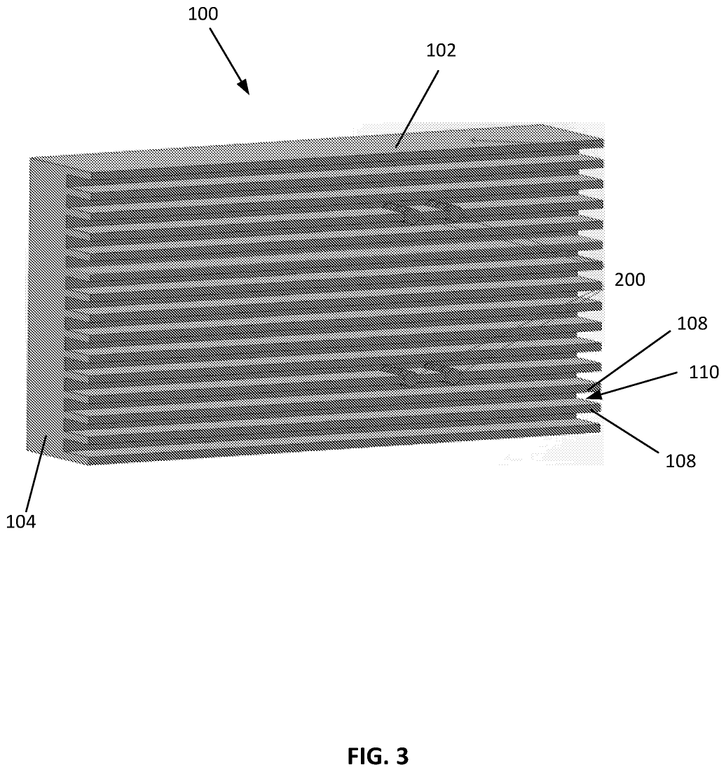

Referring to FIGS. 2 and 3, an alternative embodiment of a heat sink according to the present invention is illustrated. As shown in FIG. 2, the heat-producing or electrical device 50 has a surface 52 that is engaged by a heat sink 100. In this embodiment, the heat sink 100 has a body or block 102 of material that includes a base 104 and a cooling portion 106. The base 104 has a mounting surface 120 that is placed into contact with surface 52 of electrical device 50. The cooling portion 106 includes several fins or blades 108 that are coupled to the base 104. The fins 108 are thin blades that extend outward from the base 104 and have gaps or spaces 110 therebetween. The gaps or spaces 110 enable airflow along the fins 108 to facilitate cooling of the heat-producing device 10.

In this embodiment, multiple cooling components 200 are coupled to the base 104 of the heat sink 100. The cooling components 200 are made of a material that has a higher thermal conductivity than the base 104. In one embodiment, the base 104 is made of aluminum and the cooling components 200 are made of copper. As shown in FIG. 2, each of the cooling components 200 is placed in alignment with one of the fins 108. As a result, the cooling components 200 do not restrict airflow along the fins 108. The cooling components are a solid material, and can be referred to alternatively as a conductive plug, insert, rod, or elongate member.

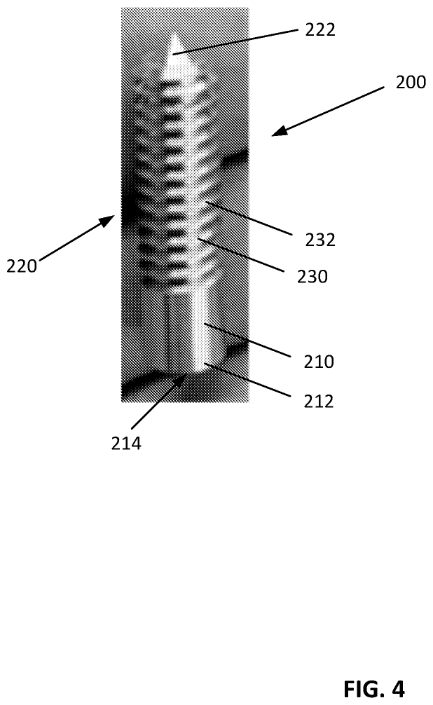

As shown in FIG. 2, and further described relative to FIG. 4, each cooling component 200 includes a mounting portion 210 that is inserted into a hole 105 (shown in dashed lines) extending through the base 104 of the heat sink 100. The mounting portion 210 has an end surface 214 that is placed into a particular location so that the end surface 214 covers the area 51 of the outer surface of the electrical device 50 located above a die 53 in the electrical device 50. As a result, the end surface 214 of the cooling component 200 is located directly over the location of the die 53, which is the part of the electrical device 50 that is cooled the most or from which the amount and rate of heat is transferred is the largest.

Referring to FIG. 3, in this embodiment, four cooling components 200 are mounted to the base 104 of heat sink 100. In other embodiments, fewer or more than four cooling components 200 can be mounted to the base 104. As shown, a few of the fins 108 have notches or gaps formed therein into which the cooling components 200 are inserted, thereby being aligned with or substantially in line with the fins 108.

Referring to FIG. 4, a side view of an embodiment of a cooling component according to the present invention is illustrated. As shown, the cooling component 200 includes a mounting portion 210 that forms a first end 212 of the cooling component 200. The first end 212 of the cooling component 200 has an end surface 214. The mounting portion 210 is inserted into a corresponding opening in the base 104 of the heat sink 100, as described in greater detail below. The cooling component 200 includes a cooling portion 220 that has a second end 222. The cooling portion 220 has an outer surface 230 that is uneven. The uneven outer surface 230 is not flat, and as a result, has an increased cooling ability relative to a cooling component 200 that has a flat outer surface. In this embodiment, the uneven outer surface 230 has threads 232 formed thereon. The threads 232 function as mini-fins or blades on the cooling component 200 along which air may flow. The threads 232 collectively increase the overall outer surface area of the cooling component 220, which improves the net cooling achieved by the cooling component 220. In different embodiments, the uneven outer surface 230 may have larger or smaller pitched threads, square-shaped threads, or another pattern of raised surfaces to increase the cooling ability of component 200.

The second or upper end 222 has a point with several different angled sides. Each of the sides functions as a cooling surface along which air can flow. Just like the threads 232, the sides of the second end 222 of the cooling component 200 increase the cooling function of the cooling component 200.

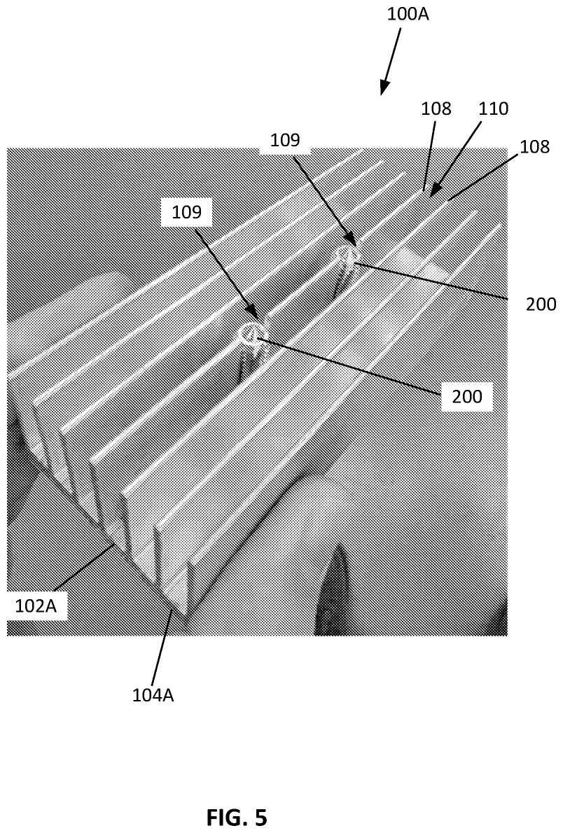

Referring to FIG. 5, a perspective view of an alternative embodiment of a heat sink according to the present invention is illustrated. In this embodiment, the heat sink 100A has a block 102A and base 104A that are thinner than those in heat sink 100. Several fins 108, spaced apart by gaps 110, extend from base 104A. A fin 108 has two cut-out portions or gaps 109 formed therein. A cooling component 200 is inserted into each of the cut-out portions or gaps 109 so that the cooling components 200 are aligned with the fins 108. This positioning of the cooling components 200 permits airflow along the gaps 110 between adjacent fins 108.

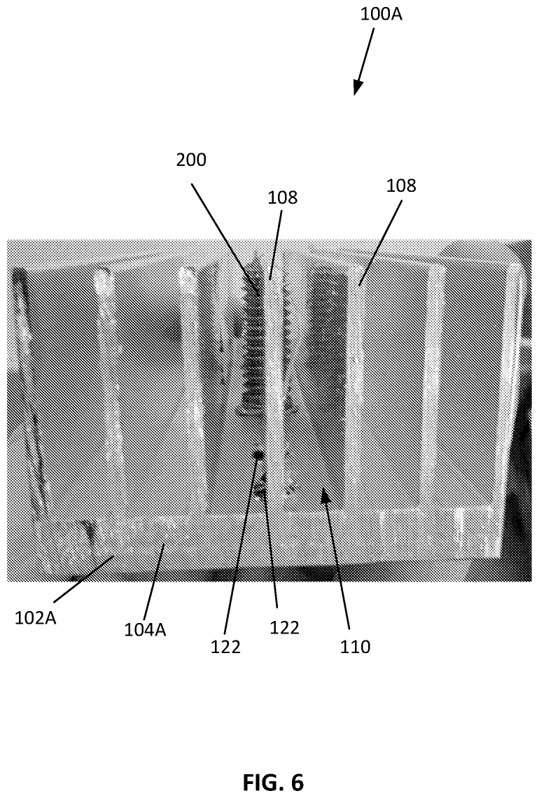

Referring to FIG. 6, an end view of the heat sink 100A is illustrated. One of the cooling components 200 can be seen as being aligned with and substantially within one of the fins 108. As shown in FIG. 6, the base 104A has a pair of mounting holes 122 that can be used to secure the heat sink 100A to an electrical device.

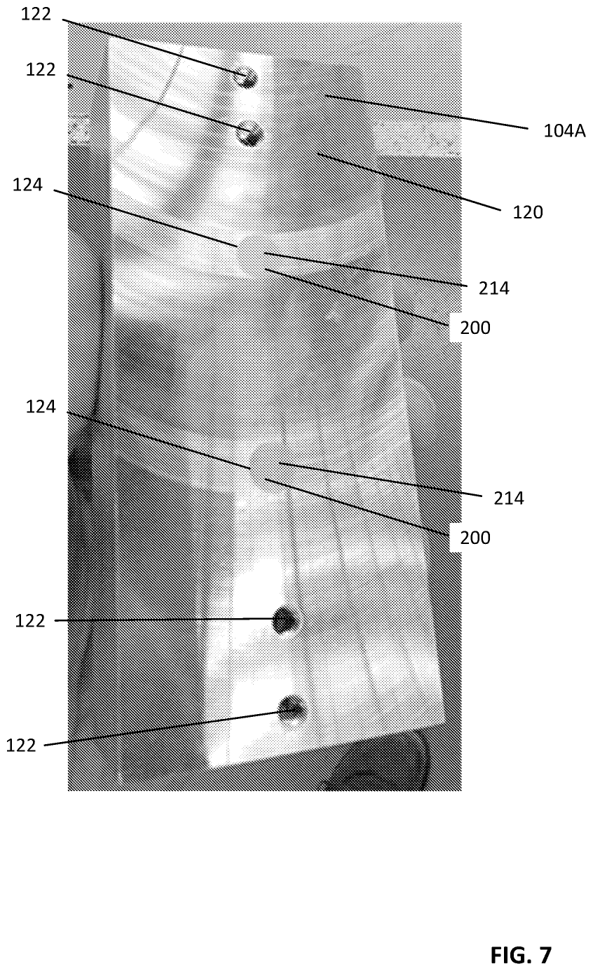

Turning to FIG. 7, a bottom view of the heat sink 100A is illustrated. As shown, the base 104A has a lower mounting surface 120 that is placed into engagement with a surface on an electrical device so that the heat sink 100A can be coupled to the electrical device. The base 104A has two pairs of mounting holes 122 proximate to opposite ends of the base 104A. The mounting holes 122 extend through the base 104A to the lower mounting surface 120. The base 104A also includes a pair of component holes 124, each of which receives the mounting portion 210 of a cooling component 200. An end surface 214 of each cooling component 200 is visible in the component holes 124, which permits the end surfaces 214 to be placed into contact with a surface of an electrical device to which the heat sink 100A is coupled. The end surfaces 214 being in contact with the electrical device enables the cooling components to absorb heat directly from the electrical device, thereby improving the cooling of the electrical device. In different embodiments, the end surface 214 can be substantially planar, angled or tapered, or have a non-uniform profile, each of which may be determined by the profile of the surface of the electrical device against which the heat sink 100A will be placed into contact. That surface of the electrical device is located near the die in the electrical device.

In different embodiments, the cooling components 200 can be mounted or coupled to the body 104 or 104A of the heat sink 100 in different ways. In one embodiment, each cooling component 200 has an interference fit or friction fit with a respective hole 105 in the body 104. In another embodiment, the body 104 is heated, thereby increasing the diameter of the openings 105. Each cooling component 200 can be inserted into one of the openings 105 and the body 104 allowed to cool, which results in the body 104 and the diameter of the openings 105 shrinking so that they tighten around the mounting portion of the cooling component 200. Ideally, no air pocket exist between the mounting portion 210 of the cooling component 200 and the walls defining the openings 105 in the body 104 (see also, FIG. 2).

In one embodiment of the invention, the heat sink is used to cool one or more dies of one or more heat-producing devices. This specific component, a die, is located in the heat-producing device and a solid cooling component 200 coupled to a heat sink 104 is positioned so that it engages or is contact with an outside surface of the electrical device at a location that is either over or close to die in the electrical device. To increase the life of a die, it is desirable to reduce the difference in temperature between the temperature of the die relative to the temperature of the heat sink block surface that is in contact with the electrical device. In one example, the die may be at 100° Celsius. The block 102 of the heat sink 100 is made of aluminum, is in contact with the heat-producing device 50, and is at 50° Celsius. The cooling component 200, which in one embodiment is made of copper, is at 70° Celsius, which is higher than the temperature of the heat sink block because the cooling component has a higher thermal conductivity. The use of the cooling component 200 transfers more heat away from the surface of the electrical device near the die, which helps cool the die and minimize the temperature differential between the die and the heat sink block surface in contact with the electrical device.

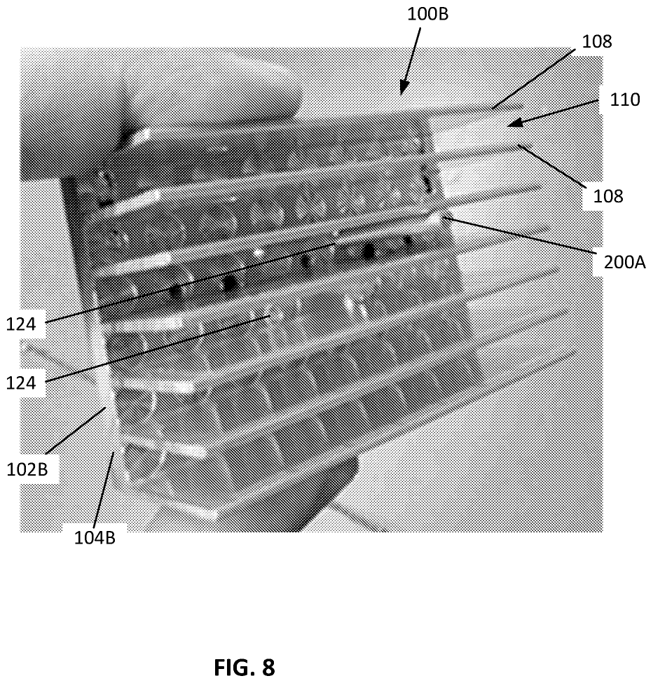

Referring to FIG. 8, a perspective view of an alternative embodiment of a heat sink according to the present invention is illustrated. Heat sink 100B includes a body or block 102B that has a base 104B from which several fins or blades 108 extend. The base 104B has several component holes 124 formed therethrough into which a cooling component 200A can be inserted. In this embodiment, cooling component 200A is a rod or elongate member that has an end that is inserted into one of the component holes 124 to couple the cooling component 200A to the base 104B. Cooling component 200A does not have external threads like cooling component 200. Also, in heat sink 100B, the component holes 124 are offset from the fins 108. The offset arrangement of component holes 124 results in the cooling components 200A being adjacent to and in contact with one of the fins 108, but not aligned therewith. The contact between cooling component 200A and one of the fins 108 results in an improvement in the cooling properties for that fin 108 because of the additional mass of the cooling component 200A absorbing heat from the heat-producing electrical device and the fin 108 with which it is in contact.

In different embodiments of the invention, the locations of the cooling components and their end surfaces can be selected to provide targeted additional cooling by the thermally conductive cooling components 200. Targeted heat transfer can target a specific die of an electrical device. Maximizing heat transfer from the electrical device to the heat sink at a first location while minimizing the heat transfer at a second location spaced from the first location may be desired. With targeted cooling of an electrical device, the effective lifetime of the heat sink may be extended. Increasing the load through a heat sink creates increased thermal cycling and wears out the heat sink. Minimizing the temperature change between a die and a surface of a heat sink increases the lifetime of the electrical device and the heat sink. Exemplary electrical devices include a welding apparatus, an insulated-gate bipolar transistor (IGBT), and other devices.

Ideally, any area of low thermal conductivity between two dissimilar heat sinks is decreased or reduced. In one embodiment, a threaded cooling component can be used with a heat sink. Areas of thermal compound and air may exist between the heat sink and the cooling component, but those areas may reduce the thermal conductivity. In another embodiment, the cooling component may be coupled to a heat sink block via a friction fit. In yet another embodiment, the cooling component may be coupled to a heat sink block via a brazed connection. One type of brazed connection is a silver brazed connection, which results in the binding material, in this case silver, having a higher thermal conductivity than the aluminum base. In an alternative embodiment, a thermal paste may be used to bind the cooling component to the heat sink base.

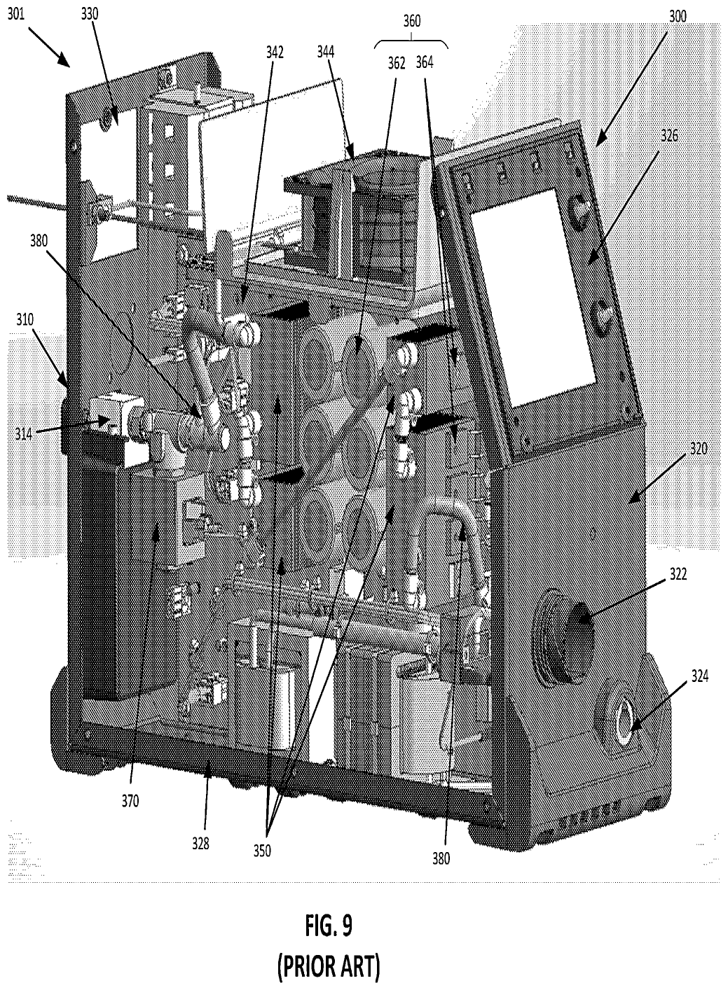

Referring to FIG. 9, a side perspective view of a prior art power source for a cutting system is illustrated with an external cover of the power source having been removed. The prior art power source 300 is used with a welding or cutting system, and supplies power to a torch assembly while also controlling the flow of gas from a gas supply to the torch assembly. In another embodiment, the power source 300 may supply the gas itself. The power source 300 includes a closed flow path 380 through which a compressed gas flows that extends from a gas inlet port 314 included on a back wall 310 of the power source 300 to an outlet port 322 included on a front wall 320 of the power source while passing through/over heat sinks 350 included in the power source 300 (the flow rate may be controlled at the inlet 314 by a flow controller 370, such as a solenoid valve assembly). When the compressed process gas reached the port 322 included on the front wall 320, the compressed process gas is directed to a torch assembly via a cable hose. Notably, for the purposes of this description, port 322 is largely described with respect to gas transfer of a single gas; however, it is to be understood that port 322 may also allow the power source 300 to transfer additional gasses and/or electricity to a torch assembly via a cable hose. By comparison, the front 320 also includes a port 324 for a cable hose that connects a working clamp to the power source 300 and, typically, port 324 only provides an electrical connection and is unrelated to gas flow. The power source 300 includes a fan 344 that creates a forced subsonic airflow.

The removed cover defines sides and a top of the power source 300 so that the cover, the back 310, and the front 320 can cooperate with a bottom 328 to form an exterior housing that defines an interior cavity 330. The interior cavity 330 houses various electrical components and a process gas cooling configuration 301. More specifically, the interior cavity 330 houses a printed circuit board (PCB) 342 that extends perpendicularly upwards from the bottom 328 (e.g., parallel to the sides of the power source 300 defined by the cover) and various electrical components 360 are mounted, either directly or indirectly, to the PCB 342. That is, the power source 300 may include electrical components 362 (e.g., capacitors) mounted directly to the PCB 342 and/or electrical components 364 mounted to heat sinks 350 (e.g., with a thermal interface) and, despite these different mountings, electrical components 362 and 364 may each be operatively coupled to the PCB 342 and may be operative to control the supply of electricity and/or gas to a torch assembly based on commands/signals received by the power source 300 (e.g., commands received at a control panel 326 included on the power source 300).

The closed flow path 380 defined by the process gas cooling configuration 301 extends through each of the heat sinks 350 included in power source 300 in series. In this embodiment, the power source 300 includes four heat sinks 350, each of which is arranged so that fins (e.g., extruded/machined surfaces) are disposed in or adjacent the flow path of the subsonic airflow generated by the fan 324. Electrical components 364 are mounted on the bases of the heat sinks 350 (e.g., the sides of the heat sinks 350 from which the fins extend away, so that the electrical components 364 are disposed on a back of the heat sinks 350). The bases of the heat sinks 350 may serve as heat transfer surfaces for heat generated by electrical components 364. As is explained in further detail below, each of the heat sinks 350 includes or defines a closed flow area (e.g., a closed pathway) that allows compressed process gas to flow through or over each of the heat sinks 350.

While the apparatuses presented herein have been illustrated and described in detail and with reference to specific embodiments thereof, it is nevertheless not intended to be limited to the details shown, since it will be apparent that various modifications and structural changes may be made therein without departing from the scope of the inventions and within the scope and range of equivalents of the claims.

In addition, various features from one of the embodiments may be incorporated into another of the embodiments. That is, it is believed that the disclosure set forth above encompasses multiple distinct inventions with independent utility. While each of these inventions has been disclosed in a preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions, and/or properties disclosed herein. Accordingly, it is appropriate that the appended claims be construed broadly and in a manner consistent with the scope of the disclosure as set forth in the following claims.

It is also to be understood that terms such as “left,” “right,” “top,” “bottom,” “front,” “rear,” “side,” “height,” “length,” “width,” “upper,” “lower,” “interior,” “exterior,” “inner,” “outer” and the like as may be used herein, merely describe points of reference and do not limit the present invention to any particular orientation or configuration. Further, the term “exemplary” is used herein to describe an example or illustration. Any embodiment described herein as exemplary is not to be construed as a preferred or advantageous embodiment, but rather as one example or illustration of a possible embodiment of the invention.

Finally, when used herein, the term “comprises” and its derivations (such as “comprising,” etc.) should not be understood in an excluding sense, that is, these terms should not be interpreted as excluding the possibility that what is described and defined may include further elements, steps, etc. Similarly, where any description recites “a” or “a first” element or the equivalent thereof, such disclosure should be understood to include incorporation of one or more such elements, neither requiring nor excluding two or more such elements. Meanwhile, when used herein, the term “approximately” and terms of its family (such as “approximate”, etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about,” “around,” “generally,” and “substantially.”

What is claimed is:

1. A heat sink for use with a heat-producing device, the heat sink comprising:
a body having a fin extending therefrom, the body being formed of a first material, the body being coupleable to the heat-producing device so that the body is in direct contact with the heat-producing device; and
a solid cooling component coupled to the body, the solid cooling component being formed of a second material, the second material being different from the first material, the second material having a higher thermal conductivity than the first material.

2. The heat sink of claim 1, wherein the heat-producing device includes a die, and the solid cooling component is placed in contact with a surface of the heat-producing device directly over the location of the die.

3. The heat sink of claim 1, wherein the solid cooling component has an outer surface that is uneven, the uneven outer surface increasing the cooling ability of the solid cooling component.

4. The heat sink of claim 1, wherein the body includes an opening formed therein, and the opening receives the solid cooling component when the solid cooling component is coupled to the body.

5. The heat sink of claim 4, wherein the opening extends through the body, and when inserted into the opening, the solid cooling component extends through the body and is positioned to directly contact the heat-producing device.

6. The heat sink of claim 4, wherein the solid cooling component has a first end, and the opening receives the first end of the solid cooling component.

7. The heat sink of claim 6, wherein an end surface of the first end directly contacts a particular location on the heat-producing device when the body is placed into engagement with the heat-producing device.

8. The heat sink of claim 1, wherein the solid cooling component contacts the fin.

9. The heat sink of claim 1, wherein the solid cooling component is substantially in line with the fin.

10. The heat sink of claim 1, wherein the first material is aluminum and the second material is copper.

11. The heat sink of claim 1, wherein the first material has a thermal conductivity of less than 240 W/m*K and the second material has a thermal conductivity greater than or equal to 400 W/m*K.

12. A heat sink for use with a heat-producing device, the heat sink comprising:
a body having a plurality of fins extending therefrom, the body being formed of a first material, the body being placeable in direct contact with a surface of a heat-producing device; and
a first solid cooling component coupled to the body proximate to a first fin of the plurality of fins, the first solid cooling component being formed of a second material different from the first material, and the second material having a higher thermal conductivity than the first material.

13. The heat sink of claim 12, wherein the body includes a first opening formed therein and extending through the body, and the first solid cooling component is inserted into the first opening of the body and placeable in direct contact with the surface of the heat-producing device.

14. The heat sink of claim 12, wherein the first solid cooling component is an elongate member.

15. The heat sink of claim 14, wherein the first solid cooling component is substantially in line with the first fin.

16. The heat sink of claim 12, wherein the body includes a second opening formed therein, and the heat sink further comprises:
a second solid cooling component coupled to the body, wherein the second solid cooling component is formed of the second material, and the second solid component is inserted into the second opening in the body.

17. The heat sink of claim 16, wherein the second solid cooling component either contacts a second fin of the plurality of fins or is located substantially in line with the second fin.

18. A heat sink comprising:
a block formed of a first material, the block having a plurality of fins extending therefrom, the block being placeable into engagement with a heat-producing device; and
a cooling component coupled to the block, the cooling component being solid and formed of a second material, the second material being different from the first material, the second material having a higher thermal conductivity than the first material.

19. The heat sink of claim 18, wherein the block includes an opening, the cooling component is insertable into the opening, and the opening and the cooling component are in contact with one of the plurality of fins.

20. The heat sink of claim 18, wherein the block includes an opening, the cooling component is insertable into the opening, and the opening and the cooling component are in line with one of the plurality of fins.
